(19) United States
(12) Patent Application Publication
(10) Pub. No.: US 2025/0311184 A1
(43) Pub. Date: Oct. 2, 2025

(54) HYBRID INTEGRATED SRAM MEMORY CELL STRUCTURE AND METHOD OF MANUFACTURING HYBRID INTEGRATED SRAM MEMORY CELL STRUCTURE

(71) Applicants: INSTITUTE OF MICROELECTRONICS, CHINESE ACADEMY OF SCIENCES, Beijing (CN); Beijing Intellectual Property Operations Management Co., Ltd, Beijing (CN)

(72) Inventors: Huaxiang YIN, Beijing (CN); Xuexiang ZHANG, Beijing (CN); Jiaxin YAO, Beijing (CN)

(21) Appl. No.: 18/838,421

(22) PCT Filed: Apr. 1, 2024
(86) PCT No.: PCT/CN2024/085268

§ 371 Date: Aug. 14, 2024

(30) Foreign Application Priority Data
Apr. 4, 2023 (CN) 202310356058.9

(51) Int. Cl. H10B 10/00

(52) U.S. Cl. CPC H10B 10/125

(57) ABSTRACT

The present disclosure relates to a hybrid integrated SRAM memory cell structure and a method of manufacturing a hybrid integrated SRAM memory cell structure. The hybrid integrated SRAM memory cell structure includes a plurality of transistors, and the plurality of transistors include a pull-up transistor, a pull-down transistor and a pass-gate transistor. At least one of the pull-up transistor, the pull-down transistor and the pass-gate transistor is a gate-all-around field effect transistor, at least one of the pull-up transistor, the pull-down transistor and the pass-gate transistor is a fin field effect transistor; and the fin field effect transistor is a superlattice stack layer fin field effect transistor.

### CROSS REFERENCE TO RELATED APPLICATION

This application is a Section 371 National Stage Application of International Application No. PCT/CN2024/085268, filed on Apr. 1, 2024, entitled “HYBRID INTEGRATED SRAM MEMORY CELL STRUCTURE AND METHOD OF MANUFACTURING HYBRID INTEGRATED SRAM MEMORY CELL STRUCTURE”, which claims priority to Chinese Patent Application No. 202310356058.9 filed on Apr. 4, 2023, which are incorporated herein by reference in their entireties.

### TECHNICAL FIELD

The present disclosure relates to a field of transistors, in particular to a hybrid integrated SRAM memory cell structure and a method of manufacturing a hybrid integrated SRAM memory cell structure.

### BACKGROUND

Feature sizes of integrated circuits continue to be miniaturized. Since gate-all-around field effect transistor (GAAFET) has a superior gate control ability, a weak short channel effect, and a large and flexible effective width design, GAAFET will serve as the next generation transistor technology and become an alternative of a fin field effect transistor (FinFET).

In the integrated circuit manufacturing, especially in SRAM, the channel width design of the transistor is important to the performance of the circuit, but it may also affect the integration density. The basic principle of SRAM is mostly to latch data through two inverters connected end to end. Each SRAM cell includes 6 or 8 transistors, which are divided into three types of transistors according to different functions: PU, PD and PG. PU (pull up) is a pull-up transistor, which is used to implement a high potential of a node, that is, a state of 1. PD (pull down) is a pull-down transistor, which is used to implement a low potential of a node, that is, a state of 0. PG (pass gate) is a pass-gate transistor, which is used to access bit lines for reading and writing. Differences of channel widths of PU, PD and PG have a significant effect on performances such as the noise margin window performance or the reading and writing speed. For example, the design of W_{PD}>W_{PG}>W_{PU} is beneficial for improving the performance of the circuit cell. Compared with traditional FinFET, SRAM with stacked nanosheets GAAFET may improve the circuit performance of SRAM by flexibly increasing or decreasing the widths of the nanosheets. However, in a case of extremely miniaturizing the pitch of devices, the circuit area is still increased, which is not conducive to further improving the transistor integration density of the integrated circuit.

### SUMMARY

A first aspect of the present disclosure provides a hybrid integrated SRAM memory cell structure, including a plurality of transistors. The plurality of transistors include a pull-up transistor, a pull-down transistor and a pass-gate transistor;
where at least one of the pull-up transistor, the pull-down transistor and the pass-gate transistor is a gate-all-around field effect transistor, and at least one of the pull-up transistor, the pull-down transistor and the pass-gate transistor is a fin field effect transistor.

A second aspect of the present disclosure provides a method of manufacturing a hybrid integrated SRAM memory cell structure, including:
providing a substrate;
epitaxially growing a superlattice stack layer on the substrate by alternately stacking a plurality of first semiconductor layers and a plurality of second semiconductor layers;
forming a plurality of fins by etching the superlattice stack layer;
forming a dummy gate on the fin and etching the fin;
selectively etching the superlattice stack layer formed by the first semiconductor layer and the second semiconductor layer on the fin to form a nanosheet stack portion, and etching off a part of a nanosheet formed by the first semiconductor layer in the superlattice stack layer from outside to inside;
forming a source/drain region by epitaxial growth;
removing the dummy gate;
covering a mask on some of the nanosheet stack portions after removing the dummy gate, and removing the first semiconductor layer in other of the nanosheet stack portions, so as to achieve a channel release in other of the nanosheet stack portions;
removing the mask;
after removing the mask, forming a gate on some of the nanosheet stack portions, so as to obtain a fin field effect transistor; and forming a gate-all-around on other of the nanosheet stack portions, so as to obtain a gate-all-around field effect transistor.

### BRIEF DESCRIPTION OF THE DRAWINGS

By reading following detailed description of preferred embodiments, various other advantages and benefits will become clear to those ordinary skilled in the art. The accompanying drawings are only for the purpose of illustrating the preferred embodiments and are not considered as a limitation of the present disclosure.

FIG. 1 is a schematic diagram of a structure after a fin is formed in the present disclosure;

FIG. 2 is a schematic diagram of a structure after a shallow trench isolation region is formed on a basis of FIG. 1;

FIG. 3 is a schematic diagram of a structure after a dummy gate is formed;

FIG. 4 is a schematic diagram of a structure after a nanosheet stack portion is formed;

FIG. 5 is a schematic diagram of a structure after a source/drain region is formed;

FIG. 6 is a schematic diagram of a structure after a dummy gate is removed;

FIG. 7 is a cross-sectional view of a structure after a dummy gate is removed and a channel is not released;

FIG. 8 is a cross-sectional view of a structure after a dummy gate is removed and a channel is released;

FIG. 9 is a cross-sectional view of a structure of a device cell after a gate is formed.

### DETAILED DESCRIPTION OF EMBODIMENTS

Hereinafter, embodiments of the present disclosure will be described with reference to the accompanying drawings. However, it should be understood that these descriptions are just exemplary and not intended to limit the scope of the present disclosure. In addition, in the following explanations, descriptions of well-known structures and technologies are omitted to avoid unnecessary obscuring the concepts of the present disclosure.

Various schematic structural diagrams according to embodiments of the present disclosure are shown in the accompanying drawings. These diagrams are not drawn to scale, in which some details are enlarged and some details may be omitted for clarity of presentation. Shapes of various regions and layers as well as relative sizes and positional relationships therebetween shown in the diagrams are just exemplary. In practice, there may be deviations due to manufacturing tolerances or technical limitations. Those skilled in the art may additionally design regions/layers with different shapes, sizes and relative positions as desired in practice.

In the context of the present disclosure, when a layer/element is referred to as being located “on” a further layer/element, the layer/element may be located directly on the further layer/element, or there may be an intermediate layer/element between them. In addition, if a layer/element is located “on” a further layer/element in an orientation, the layer/element may be located “below” the further layer/element when the orientation is reversed.

The width quantization problem of traditional FinFET limits the optimization development of the performance and area of SRAM. The emergence of stacked nanosheets GAAFET provides a new path for breaking through this problem. The stacked nanosheets GAAFET improves the circuit performance of SRAM by flexibly increasing or decreasing the widths of the nanosheets. However, the circuit area is still increased in a case of extremely miniaturizing the pitch of devices, which is not conducive to further improving the transistor integration density of the integrated circuit.

The main purpose of the present disclosure is to provide a hybrid integrated SRAM memory cell structure and a method of manufacturing a hybrid integrated SRAM memory cell structure. A FinFET structure with a larger driving current and a GAAFET structure with a smaller driving current are respectively formed at different positions by selecting some regions not to perform the channel release and selecting remaining regions to perform the channel release, thereby achieving a hybrid integration of GAAFET and FinFET. The circuit area is not increased when designing the transistor scales, which is more conducive to further improving the integration density.

In the SRAM memory cell array of the present disclosure, a superlattice stack layer FinFET (SL-FinFET, that is, a channel is formed by a superlattice stack layer) structure with a larger driving current is formed at a specific position by selecting some regions not to perform the channel release, and a GAAFET structure with a smaller driving current is formed by performing the channel release in the remaining regions. In this way, a hybrid integration of GAAFET and SL-FinFET is achieved, and driving currents with two different sizes are achieved under a same projection area, thereby greatly improving the circuit performance of SRAM.

Regions for forming the FinFET structure and the GAAFET structure may be freely selected and divided, so that transistors with different functions adopt different structures. For example, the SRAM memory cell structure generally includes a plurality of transistors. The plurality of transistors include a pull-up transistor, a pull-down transistor and a pass-gate transistor. At least one of the pull-up transistor, the pull-down transistor and the pass-gate transistor is a gate-all-around field effect transistor, and at least one of the pull-up transistor, the pull-down transistor and the pass-gate transistor is a fin field effect transistor.

Electrical performances of hybrid integrated structures with different layouts have different focuses, including but not limited to the following examples.

In some embodiments, a PG transistor and a PU transistor are GAAFETs, while a PD transistor is SL-FinFET. In this embodiment, a circuit design of PD>PG>PU is achieved in a case of not increasing the circuit area, which may improve the noise margin window performance of SRAM, thereby improving the circuit performance.

In some embodiments, the PU transistor is GAAFET, while the PG transistor and the PD transistor are SL-FinFETs. In this way, the driving current of the PG transistor is increased and a reading and writing speed is improved, thereby achieving the high-speed SRAM cell and reducing the circuit area.

On the basis of the hybrid integration of GAAFET and SL-FinFET, the circuit performance of SRAM may be further improved by flexibly increasing or decreasing the width or height of the fin (changing the width of the fin will change the width of the nanosheet). In this way, the means for adjusting the circuit performance is added, and multiple means may be combined to adjust the circuit performance of SRAM in a wider range.

In some embodiments, channel widths of a plurality of transistors are different.

In some embodiments, the widths of at least two of the pull-up transistor, the pull-down transistor and the pass-gate transistor are different.

In some embodiments, a width of the PD transistor is greater than a width of the PG transistor, and the width of the PG transistor is greater than a width of the PU transistor.

In some embodiments, a width of the PD transistor is greater than a width of the PG transistor, and the width of the PG transistor is equal to a width of the PU transistor.

In some embodiments, a width of the PD transistor is equal to a width of the PG transistor, and the width of the PG transistor is greater than a width of the PU transistor.

The “channel width” in the present disclosure refers to a width surrounded by a gate.

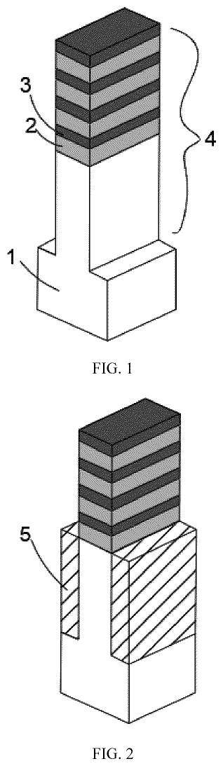

The present disclosure further provides a method of forming an SRAM memory cell structure by hybrid integrating GAAFET and SL-FinFET. For convenience of display, in the following, a method of manufacturing a device is used to illustrate a method of manufacturing a device array. FIG. 1 to FIG. 9 are schematic diagrams of a process of manufacturing the SRAM memory cell structure of the present disclosure.

In step S1, a substrate 1 is provided. The substrate 1 may be any substrate known to those skilled in the art for carrying elements of a semiconductor integrated circuit, such as silicon-on-insulator (SOI), bulk silicon, silicon carbide, germanium, silicon germanium, gallium arsenide, or germanium-on-insulator. A corresponding top layer semiconductor material is silicon, germanium, silicon germanium, or gallium arsenide. A highly doped well region is formed by injecting impurities into the substrate, diffusion and annealing, so as to achieve a desired well depth. For a P-type FET, the highly doped well region mentioned above is an N-type well, and the injected impurities are n-type impurity ions, such as phosphorus (P) ions. For an N-type FET, the highly doped well region mentioned above is a p-type well, and the injected impurities are p-type impurity ions, such as boron (B) ions.

In step S2, a superlattice stack layer, which is composed of a plurality of periods of first semiconductor layer 2/second semiconductor layer 3, is epitaxially grown on the substrate 1. The first semiconductor layer 2 and the second semiconductor layer 3 are made of two different semiconductor materials, which may be any combination of materials depending on the device performance, including but not limited to common SiGe and Si. For GAAFET, one of the first semiconductor layer 2 and the second semiconductor layer 3 is used as a sacrificial layer of GAAFET, and the other of the first semiconductor layer 2 and the second semiconductor layer 3 is used as a channel of GAAFET. For SL-FinFET, an entire superlattice stack layer is used as a channel of SL-FinFET. Taking a stack layer of SiGe and Si as an example, a thickness of SiGe and a thickness of Si may be adjusted separately during an epitaxy process of the superlattice stack layer, and the content of Ge may also be adjusted to form a multi-component Si/SiGe stack layer.

Next, in step S3, a plurality of periodically distributed fins 4 are formed by etching the epitaxial grown superlattice stack layer. This step may be achieved by a self-aligned spacer image transfer (SIT) process, and the fins are formed by using auxiliary structures, such as a spacer, a sacrificial layer and a hard mask. Specifically, a first spacer may be provided on the superlattice stack layer; and the superlattice stack layer is etched by using the first spacer as a mask, so as to form the plurality of fins.

An upper portion of the fin 4 is a conductive channel region formed by the superlattice stack layer, and a lower portion of the fin 4 is the substrate, forming the fin as shown in FIG. 1. The fin 4 is used to form one or more horizontal nanosheets of n-type field effect transistors and/or p-type field effect transistors.

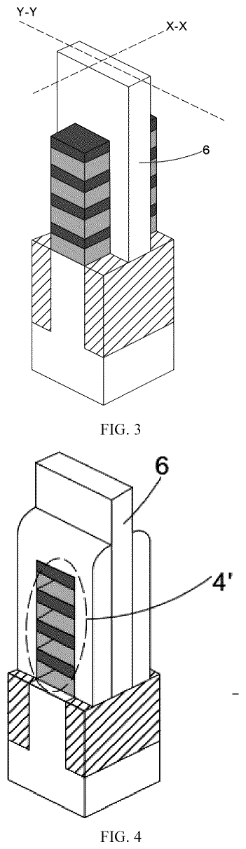

In step S3, the superlattice stack layer may be etched by using a pattern design of the mask, so as to form a plurality of fins with different widths for forming channels with different widths. The circuit performance of SRAM may also be improved through the width. By combing the width with the hybrid integration of GAAFET and SL-FinFET, more combination methods may be provided for improving the circuit performance. The width here refers to the width in a Y-Y direction as shown in FIG. 3.

In step S4, a shallow trench isolation (STI) region 5 is formed between adjacent two fins, as shown in FIG. 2. The shallow trench isolation region 5 may be formed by a suitable dielectric material, such as silicon dioxide (SiO₂), silicon nitride (SiNₓ), etc. The shallow trench isolation region 5 is used to separate transistors on the adjacent fins.

In step S5, a dummy gate 6 is formed on the exposed fin 4, as shown in FIG. 3. The dummy gate 6 is generally a multi-layer structure, including at least one of a gate insulation dielectric layer, a dummy gate layer and a hard mask layer. The dummy gate 6 may be formed by processes such as thermal oxidation, chemical vapor deposition and sputtering. The dummy gate 6 spans across the superlattice stack layer located at the upper portion of the fin 4. FIG. 3 defines cross-sectional directions of respective cross-sectional views, in which two dashed lines X-X and Y-Y are shown. The line X-X represents a centerline of the fin along a fin line direction, and the line Y-Y represents a centerline of the fin perpendicular to the fin line direction. Subsequent accompanying drawings are cross-sectional views taken along line X-X and line Y-Y.

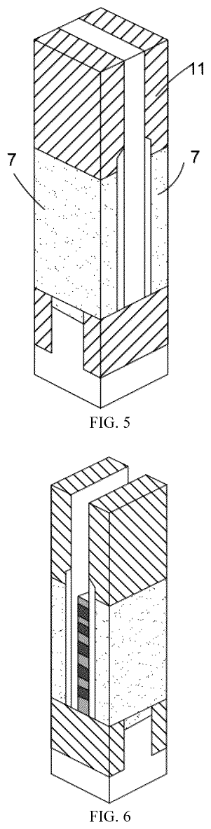

In step S6, a source/drain region is formed. A second spacer of silicon nitride is provided on both sides of the dummy gate 6 in the X-X direction. Then, by using the dummy gate 6 and the second spacer as a mask, the fin is etched through an etching process, and the fin structure between adjacent dummy gates is etched off, so as to form a growth space for source/drain. The source/drain region is epitaxially grown in the growth space. A plurality of inner spacer processes are used when forming the growth space for source/drain. At the same time, the fin is selectively etched to form a nanosheet stack portion 4′ (at the dashed box in FIG. 4), and a part of a nanosheet formed by the first semiconductor layer in the superlattice stack layer is etched off from outside to inside by a pull-back process, as shown in FIG. 4. Afterwards, a dielectric material such as silicon nitride may be deposited, and the growth space for source/drain may be formed by etching back. A source/drain region 7 is epitaxially grown and doped in the growth space. Then, an isolation layer 11 is deposited on an upper surface of the dummy gate 6 and an upper surface of the source/drain region 7, so as to prevent interconnection short circuits between the dummy gate 6 and the source/drain region 7 in subsequent steps. Chemical mechanical polishing is performed on the isolation layer 11, so that the isolation layer 11 is planarized and the dummy gate 6 is exposed, as shown in FIG. 5.

In step S7, the dummy gate 6 is removed. The dummy gate 6 is removed by selective etching or a corrosion process, as shown in FIG. 6.

The next step is an important step for the hybrid integration of GAAFET and SL-FinFET.

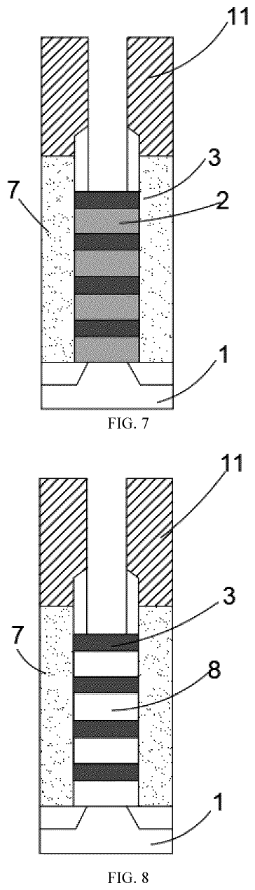

In step S8, a mask is covered on some nanosheet stack portions 4′, and the first semiconductor layers in remaining nanosheet stack portions 4′ are removed, so as to achieve the channel release in the remaining nanosheet stack portions. The nanosheet stack portion where the channel release is performed is used to form GAAFET, while the nanosheet stack portion where the channel release is not performed is used to form SL-FinFET. When performing the channel release in this step, the material of the removed first semiconductor layer 2 may be adjusted according to requirements, such as a silicon germanium layer. The structure of the nanosheet stack portion where the channel release is not performed is shown in FIG. 7. The structure of the nanosheet stack portion where the channel release is performed is shown in FIG. 8, where the first semiconductor layer 2 is etched off to form a cavity 8. The cross-sectional direction of each of FIG. 7 and FIG. 8 is the X-X direction. The distribution of these two types of nanosheet stack portions on the substrate depends on the device requirements. The mask pattern in this step determines the distribution of a GAAFET array and an SL-FinFET array. Therefore, corresponding mask patterns may be selected in this step according to the circuit requirements of the pull-up transistor, the pull-down transistor and the pass-gate transistor.

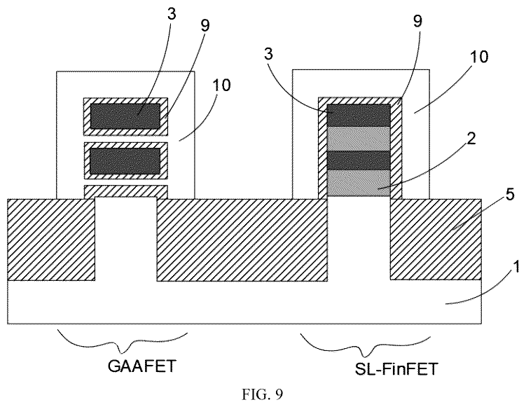

In step S8, the mask provided in the step S7 is removed, and then gates are formed synchronously in the region where the channel release is performed and the region where the channel release is not performed. The structure of the gate is determined by the structure of the nanosheet stack portion. A gate-all-around is formed on the nanosheet stack portion where the channel release is performed, so as to obtain GAAFET. A gate with a covering structure is formed on the nanosheet stack portion where the channel release is not performed, so as to obtain SL-FinFET. In order to clearly display the integration of two different transistor structures, FIG. 9 illustrates a cross-sectional view in Y-Y direction. The left side of FIG. 9 shows GAAFET, where the channel is the second semiconductor layer 3, and the channel is surrounded by a gate dielectric layer 9 and a metal gate 10 in sequence. The right side of FIG. 9 shows SL-FinFET, where the channel is the nanosheet stack portion formed by alternately stacking the first semiconductor layer 2 and the second semiconductor layer 3, and the channel is covered by the gate dielectric layer 9 and the metal gate 10. In FIG. 9, GAAFET is adjacent to SL-FinFET, but the present disclosure is not limited to this. In practical applications, GAAFET and SL-FinFET may not be adjacent to each other.

Finally, the interlayer dielectric is filled, various electrodes are in contact with each other and interconnected, and bonding pads are led out (not shown in the figures).

Compared with the related art, the present disclosure achieves the following technical effects:
(1) In the SRAM memory cell structure, transistors with different functions adopt transistors with different types. For example, any combination of GAAFET and FinFET may be selected to form memory devices that meet different functional requirements, which greatly improves the circuit performance of SRAM without increasing the circuit area.
(2) After removing the dummy gate, a superlattice stack layer FinFET structure with a larger driving current and a GAAFET structure with a smaller driving current are respectively formed at different positions by selecting some nanosheet stack portions not to perform the channel release and selecting the remaining nanosheet stack portions to perform the channel release, thereby achieving the hybrid integration of GAAFET and FinFET. The circuit area is not increased when designing the transistor scales, which is more conducive to further improving the integration density.

The embodiments of the present disclosure are described above. However, these embodiments are for illustrative purposes only and are not intended to limit the scope of the present disclosure. The scope of the present disclosure is defined by the attached claims and their equivalents. Without departing from the scope of the present disclosure, those skilled in the art may make various substitutions and modifications, all of which should fall within the scope of the present disclosure.

1. A hybrid integrated SRAM memory cell structure, comprising a plurality of transistors, wherein the plurality of transistors comprise a pull-up transistor, a pull-down transistor and a pass-gate transistor,
wherein at least one of the pull-up transistor, the pull-down transistor and the pass-gate transistor is a gate-all-around field effect transistor, at least one of the pull-up transistor, the pull-down transistor and the pass-gate transistor is a fin field effect transistor; and the fin field effect transistor is a superlattice stack layer fin field effect transistor.

2. The hybrid integrated SRAM memory cell structure of claim 1, wherein the pass-gate transistor and the pull-up transistor are gate-all-around field effect transistors, and the pull-down transistor is the fin field effect transistor.

3. The hybrid integrated SRAM memory cell structure of claim 1,
wherein the pull-up transistor is the gate-all-around field effect transistor, and the pass-gate transistor and the pull-down transistor are fin field effect transistors; or
wherein the pull-down transistor is the gate-all-around field effect transistor, and the pass-gate transistor and the pull-up transistor are fin field effect transistors.

4. The hybrid integrated SRAM memory cell structure of claim 1, wherein channel widths of the plurality of transistors are different.

5. The hybrid integrated SRAM memory cell structure of claim 1, wherein channel widths of at least two of the pull-up transistor, the pull-down transistor and the pass-gate transistor are different.

6. A method of manufacturing a hybrid integrated SRAM memory cell structure, comprising:
providing a substrate;
epitaxially growing a superlattice stack layer on the substrate by alternately stacking a plurality of first semiconductor layers and a plurality of second semiconductor layers;
forming a plurality of fins by etching the superlattice stack layer;
forming a dummy gate on the fin and etching the fin;
selectively etching the superlattice stack layer formed by the first semiconductor layer and the second semiconductor layer on the fin to form a nanosheet stack portion, and etching off a part of a nanosheet formed by the first semiconductor layer in the superlattice stack layer from outside to inside;
forming a source/drain region by epitaxial growth;
removing the dummy gate;
covering a mask on some of the nanosheet stack portions after removing the dummy gate, and removing the first semiconductor layer in other of the nanosheet stack portions, so as to achieve a channel release in other of the nanosheet stack portions;
removing the mask;
after removing the mask, forming a gate on some of the nanosheet stack portions, so as to obtain a fin field effect transistor; and forming a gate-all-around on other of the nanosheet stack portions, so as to obtain a gate-all-around field effect transistor.

7. The method of claim 6, wherein the forming a plurality of fins comprises:
providing a first spacer on the superlattice stack layer; and
etching the superlattice stack layer by using the first spacer as a mask, so as to form the plurality of fins.

8. The method of claim 7, further comprising:
forming a shallow trench isolation region,
wherein the forming a shallow trench isolation region comprises: forming the shallow trench isolation region between adjacent fins on the substrate.

9. The method of claim 8, further comprising:
forming a source/drain region,
wherein the forming a source/drain region comprises: etching off the fin between adjacent dummy gates, so as to form a growth space for source/drain; and epitaxial growing the source/drain region in the growth space.

10. The method of claim 6, wherein the forming a plurality of fins comprises:
etching the superlattice stack layer by using a pattern design of a mask, so as to form the plurality of fins with different widths.
